(19) United States
(12) Patent Application Publication
(10) Pub. No.: US 2003/0113588 A1
(43) Pub. Date: Jun. 19, 2003

(54) Magnetic recording medium and method of manufacturing the same

(76) Inventors: Hiroyuki Uwazumi, Nagano (JP); Tadaaki Oikawa, Nagano (JP); Takahiro Shimizu, Nagano (JP); Naoki Takizawa, Nagano (JP); Miyabi Nakamura, Ibaragi (JP)

Correspondence Address: ROSSI & ASSOCIATES, P.O. Box 826, Ashburn, VA, 20146-0826, US

(21) Appl. No.: 10/303,675

(22) Filed: Nov. 25, 2002

(30) Foreign Application Priority Data
Nov. 26, 2001 (JP) 2001-359959

(51) Int. Cl. C23C 14/00

(52) U.S. Cl. 428/694 TS; 428/694 T; 204/192.11

(57) ABSTRACT

A magnetic recording medium has a nonmagnetic substrate, a nonmagnetic underlayer containing at least one metal selected from Ru, Os, and Re laminated on the substrate, and a magnetic layer including ferromagnetic crystal grains and nonmagnetic grain boundaries surrounding the ferromagnetic crystal grains laminated on the underlayer. The underlayer is deposited in a gas atmosphere containing argon and at least one of krypton and xenon in an amount sufficient to reduce the argon remaining in the underlayer to less than 1,000 ppm. Such a gas atmosphere contains at least 10% of krypton or xenon, and pressurized to a range of 30-70 mTorr. The underlayer is formed having film structure composed of fine particles, which is suitable for controlling the structure of the magnetic layer.

### BACKGROUND

On a magnetic recording medium that needs high recording density and low noise, various composition and structure of the magnetic layer, and materials for the nonmagnetic underlayer have been proposed so far. Recently, a magnetic layer, generally called a granular magnetic layer, has been proposed having structure in which each of magnetic grains is surrounded by nonmagnetic and nonmetallic matter, such as oxide or nitride. For example, U.S. Pat. No. 5,679,473 discloses that by an RF sputtering method using a CoNiPt target containing an oxide, such as SiO₂, a granular recoding film can be formed having a structure in which each of the magnetic grains is surrounded and separated by nonmagnetic oxide, to attain high coercive force Hc and low noise. Because the granular magnetic layer, which is different from the conventional magnetic layers, does not need substrate heating for structure control, the magnetic layer achieves high productivity and allows usage of an inexpensive substrate made of plastic.

Moreover, it has been reported recently that performances of a magnetic recording medium having a granular magnetic layer can also be improved by structure control of the underlayer. For example, Digests of the 24th Annual Conference on Magnetics in Japan, page 21 (2000) discloses that high Hc and low noise can be attained by providing a ruthenium (Ru) layer under the granular layer. The present inventors further discovered that the grain size, grain boundary structure, and the alignment of the granular magnetic layer strongly depend on the thickness of the ruthenium underlayer and the deposition conditions when ruthenium is used in the nonmagnetic underlayer for the granular magnetic layer.

Deposition by sputtering in an argon gas atmosphere is generally employed for laminating a nonmagnetic underlayer and a magnetic layer on a magnetic recording medium. The power of the deposition and the pressure of the argon gas atmosphere significantly affect the fine structure of the magnetic layer through the variation of the fine structure of the ruthenium underlayer.

There is a need for a magnetic recording medium exhibiting excellent performance by controlling fine structure of the magnetic layer through controlling fine structure of the nonmagnetic underlayer. The present invention addresses this need.

### SUMMARY OF THE INVENTION

The present invention relates to a magnetic recording medium that is mountable on a magnetic recording device, including an external memory device of a computer, and to a method of manufacturing such a medium, in particular to a method for depositing a nonmagnetic underlayer by sputtering, and to a magnetic recording medium manufactured by such a method.

According to one aspect of the present invention, a magnetic recording medium has a nonmagnetic substrate and a nonmagnetic underlayer and a magnetic layer sequentially laminated on the substrate. The nonmagnetic layer contains at least one metal selected from Ru, Os, and Re. The magnetic layer is composed of ferromagnetic grains and nonmagnetic grain boundaries surrounding the ferromagnetic grains, sequentially laminated on the nonmagnetic substrate. The underlayer contains less than 1,000 ppm of the atoms of the inert gas, namely argon, used during the depositing process of the underlayer.

The film structure of the underlayer can be formed while reducing the concentration of the inert gas, such as argon, entrapped within the underlayer during the depositing process, which remains in the underlayer, to a value below a standard value, preferably less than 1,000 ppm. The nonmagnetic underlayer can be formed of a film structure composed of fine particles. The film structure of the underlayer can be used to control the film structure of the magnetic layer.

Another aspect of the present invention is a method of manufacturing the magnetic recording medium described above. The underlayer is deposited while reducing the concentration of the atoms of the inert gas in the underlayer on the nonmagnetic substrate by reactive sputtering in a gas atmosphere containing at least one type inert gas, such as krypton or xenon, that reduces the atom count of the inert gas remaining in the underlayer to a predetermined level, or a combination of at least two types of inert gases to reduce the atom count of at least one of the gases remaining in the underlayer to the predetermined level. The magnetic layer is then deposited on the underlayer. The concentration of the atoms of one of the inert gases remaining in the underlayer can be reduced by mixing the one inert gas with a different inert gas having larger atomic weight and radius. The one inert gas can be argon and the different inert gas can be krypton or xenon for reducing argon remaining in the underlayer.

If argon gas is used, the gas atmosphere can contain a sufficient amount of krypton or xenon to reduce argon remaining in the underlayer to less than 1,000 ppm. Such a gas atmosphere can contain at least 10% of krypton or xenon, preferably at least 50% of krypton or xenon, and more preferably at least 80% of krypton or xenon. The gas atmosphere can be pressurized to a range of 30-70 mTorr. The underlayer and the magnetic layer can be deposited without preheating the nonmagnetic substrate.

Another aspect of the present invention is the magnetic recording medium formed by the method described above.

### BRIEF DESCRIPTION OF THE DRAWINGS

FIG. 1 schematically illustrates the layer structure of a magnetic recording medium according to the present invention.

FIG. 2 is a graph showing variation of coercive force He as a function of the concentration of krypton or xenon in the gas in the process of depositing a nonmagnetic underlayer.

FIG. 3 is a graph showing variation of the concentration of argon atoms contained in the underlayer as a function of the concentration of krypton or xenon in the gas in the process of depositing a nonmagnetic underlayer.

FIG. 4 is a graph showing variation of the coercive force Hc and SNR as a function of the pressure of the atmosphere in the process for depositing the nonmagnetic underlayer.

### DETAILED DESCRIPTION

The present inventors have made extensive studies on conditions for depositing the ruthenium underlayer and found that fine structure of the ruthenium underlayer is favorably controlled when argon gas used in deposition by sputtering is mixed with krypton or xenon, which is an inert gas like argon but having an atomic weight and an atomic radius larger than those of argon. In a magnetic recording medium, the concentration of a predetermined type of an inert gas that is entrapped during the deposition process of the nonmagnetic underlayer and remaining in the underlayer is reduced below a certain standard value. By reducing the concentration of the trapped inert gas, the grain size of the nonmagnetic underlayer is controlled in a predetermined unit and the underlayer is formed having a film structure that is precise and composed of fine particles, which is appropriate to structure control of the magnetic film of the magnetic layer.

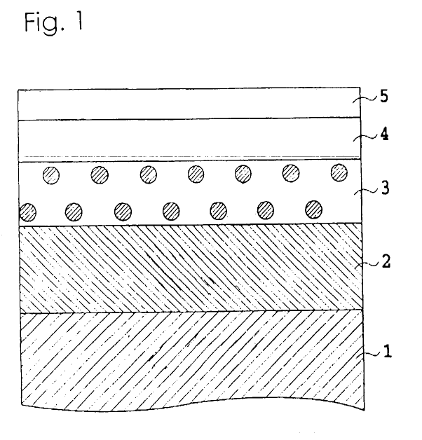

FIG. 1 shows a structure of a magnetic recording medium according to the present invention. This magnetic recording medium comprises a nonmagnetic substrate 1, and the following layers sequentially formed on the substrate: a nonmagnetic underlayer 2, a granular magnetic layer 3, and a protective film 4, and a liquid lubricant layer 5. A nonmagnetic seed layer also can be provided between the nonmagnetic substrate 1 and the nonmagnetic underlayer 2, or a nonmagnetic intermediate layer can be provided between the nonmagnetic underlayer 2 and the granular magnetic layer 3, to control crystal alignment and other structure of the underlayer 2 or the granular magnetic layer 3. Even with these optional layer(s), the effect of the invention can still obtained, and even better performance can be achieved.

The nonmagnetic substrate 1 can be formed of a NiP-plated aluminum alloy, strengthened glass, or crystallized glass, which are all employed in a common magnetic recording medium. In addition, a substrate made by injection-molding of polycarbonate, poly olefin, or other resin can be used because substrate heating is not required. The protective film 4 is a thin film mainly composed of carbon that can be deposited by a sputtering method or a CVD method, for example. The liquid lubricant layer 5 can be formed of perfluoropolyether lubricant, for example.

The magnetic layer 3 in the present invention is a so-called granular magnetic layer 3 composed of ferromagnetic crystal grains and nonmagnetic grain boundaries surrounding the grains. The grain boundary is composed of oxide or nitride of metal. Such a structure can be manufactured by deposition by means of sputtering using a target of ferromagnetic metal containing oxide that composes the nonmagnetic grain boundary region. Alternatively, the structure can be manufactured by deposition by means of reactive sputtering in an oxygen-containing argon gas using a target of ferromagnetic metal. The material for composing the ferromagnetic grains is preferably a CoPt alloy. Addition of Cr, Ni, or Ta to the CoPt alloy is particularly favorable in reducing media noise. The material for composing the nonmagnetic grain boundary region can be an oxide of Cr, Co, Si, Al, Ti, Ta, Hf, or Zr, which is particularly favorable in forming a stable granular structure. The magnetic layer 3 need only be thick as necessary and sufficient to gain enough head reproduction output at reading out of a record.

The nonmagnetic underlayer 2 can be made of nonmagnetic metal containing at least one of Ru, Os, and Re. The amount of argon atoms contained in the nonmagnetic underlayer 2 is maintained at or below a standard value of 1,000 ppm. Such a structure allows formation of a precise and fine film as compared with an underlayer containing more argon atoms. Such a nonmagnetic underlayer favorably controls the film structure of the granular magnetic layer 3.

The magnetic recording medium can be manufactured by laminating the nonmagnetic underlayer 2 containing at least one metal selected from Ru, Os, and Re on the nonmagnetic substrate 1, and laminating the granular magnetic layer 3 composed of ferromagnetic crystal grains and nonmagnetic grain boundaries surrounding the grains on the underlayer 2.

According to the present invention, the nonmagnetic underlayer 2 is laminated by reactive sputtering using at least one type of inert gas. The quantity of the predetermined type of inert gas that is entrapped in the nonmagnetic underlayer during deposition process of the underlayer and remaining in the underlayer is controlled to reduce below the standard value of 1,000 ppm. Gases used in the deposition can be krypton or xenon gas, or argon gas in combination with one or more types of inert gases. For example, the other inert gas can be one of krypton and xenon gases, which have an atomic weight and an atomic radius larger than those of argon gas. For example, a combination of argon gas and one of krypton and xenon gases, which have an atomic weight and an atomic radius larger than those of argon gas, is preferred. Thus, the concentration of argon gas that is entrapped during the deposition of the nonmagnetic underlayer 2 and remaining in the underlayer is reduced below a standard value of 1,000 ppm. By reducing the entrapped argon gas, the grain size of the nonmagnetic underlayer is controlled in a predetermined unit and the underlayer is formed having a film structure that is precise and composed of fine particles, which is appropriate to structure control of the magnetic film of the magnetic layer.

By reducing the argon gas concentration remaining in the film of the nonmagnetic underlayer 2 below the standard value of 1,000 ppm, the grain size in the nonmagnetic underlayer 2 can generally be controlled in the range from several nm to teen nm. Because the nonmagnetic underlayer 2 is composed of fine particles, by controlling the concentration of argon gas, density of the underlayer increases and the film structure of the underlayer becomes more precise. By forming the nonmagnetic underlayer 2 having precise and fine structure, variation of layer structure of the nonmagnetic underlayer 2 can be effectively transmitted to the granular magnetic layer 3, to facilitate control of the layer structure of the granular magnetic layer 3. Thus, magnetic characteristics and electromagnetic conversion characteristic can be improved with the present method, since control of grain size and promotion of grain boundary segregation are facilitated in the granular magnetic layer 3.

The gas mixture of the deposition atmosphere can contain at least 10% of krypton or xenon, and preferably, at least 50% of krypton or xenon. The maximum effect can be obtained when the gas contains at least 80% of krypton or xenon. The pressure of the deposition atmosphere in the range from 30 mTorr to 70 mTorr is preferable for structure control of the nonmagnetic underlayer 2 made of ruthenium.

When the atoms having large atomic weight are used during sputtering, the number of atoms entrapped in the film decreases. Further, since the inert gas atoms that recoil from the target and collide with the substrate during the deposition process decrease, shock against the thin film during deposition is reduced, and control of the film structure of the underlayer can be further facilitated. Similar effects can be obtained when both krypton and xenon are used mixing with argon.

When a deposition gas containing krypton or xenon, which has the atomic weight and the atomic radium larger than those of argon and is an inert gas like argon, is used, the number of argon atoms that are entrapped in the nonmagnetic underlayer 2 of ruthenium can be reduced below 1,000 ppm. That means the amount of argon remaining in the underlayer can be reduced to less than 1,000 ppm. The reduced amount of remained argon gas enhances the effect to control film structure of the granular magnetic layer 3 and improves electrical and mechanical characteristics of the magnetic layer.

In production of a magnetic recording medium shown in FIG. 1 having layer structure described above, a step of heating (necessary in a conventional production process) a substrate can be omitted. Even if the heating step is omitted in the production process of the invention, high coercive force He and low media noise can be attained. Reduction in production cost can also be achieved accompanying simplification of the production process. Also, plastics, which are inexpensive materials, can be used for a substrate in addition to conventionally used aluminum and glass substrates. The thickness need only be sufficient to control the structure of the granular magnetic layer 3, as well as productivity and production cost.

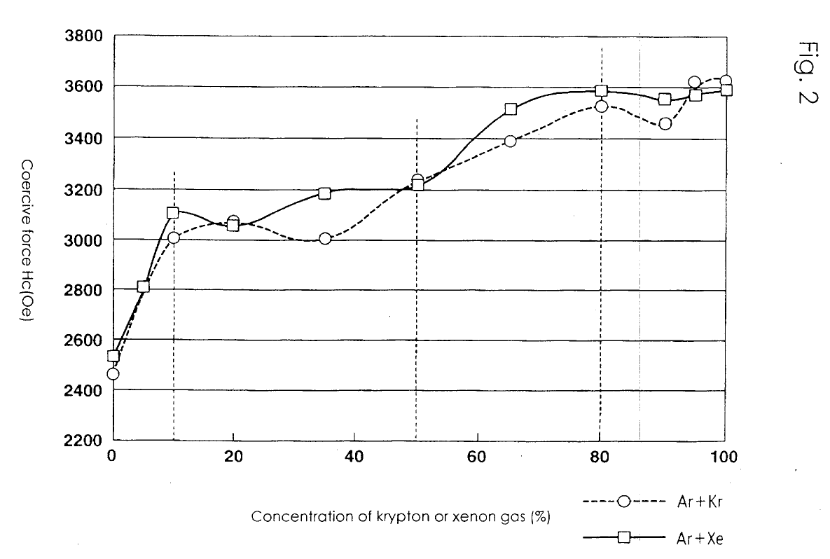

Referring to FIGS. 2 to 4, examples of magnetic recording media produced according to the present invention are described. In a first example, a magnetic recording medium having structure shown in FIG. 1 was produced by introducing into a sputtering apparatus a cleaned 3.5″ nonmagnetic disk made by injection-molding polycarbonate resin. Mixed gases of both argon/krypton and argon/xenon were separately used in the deposition process. The pressure of the deposition atmosphere was fixed at 30 mTorr, while varying the mixing ratio (to produce a plurality of examples under both argon/krypton and argon/xenon mixtures). A nonmagnetic underlayer 2 having a thickness of 20 nm was formed of ruthenium. A granular magnetic layer 3 having thickness of 15 nm was formed by RF (radio frequency) sputtering using a target of Co₇₆Cr₁₂Pt₁₂ containing 10 mol % of SiO₂ under argon gas pressure of 5 mTorr. After a carbon protective film 4 with a thickness of 10 nm was deposited, the resulting substrate was taken out from the vacuum chamber. Then, a liquid lubricant was applied to form a liquid lubricant layer 5 having a thickness of 1.5 nm, to obtain a magnetic recording medium having structure shown in FIG. 1. In this production process, substrate heating before deposition was not executed.

FIG. 2 shows variation of coercive force He of a medium measured by VSM (vibrating sample magnetometer) as a function of the concentration of krypton and xenon gas contained in the deposition process gas. FIG. 2 shows that coercive force He increases with increase of addition of krypton or xenon. FIG. 2 also demonstrates that at least 10% of krypton or xenon is necessary to attain favorable characteristic. More preferably, at least 50%, and most preferably, at least 80% of krypton or xenon can be used.

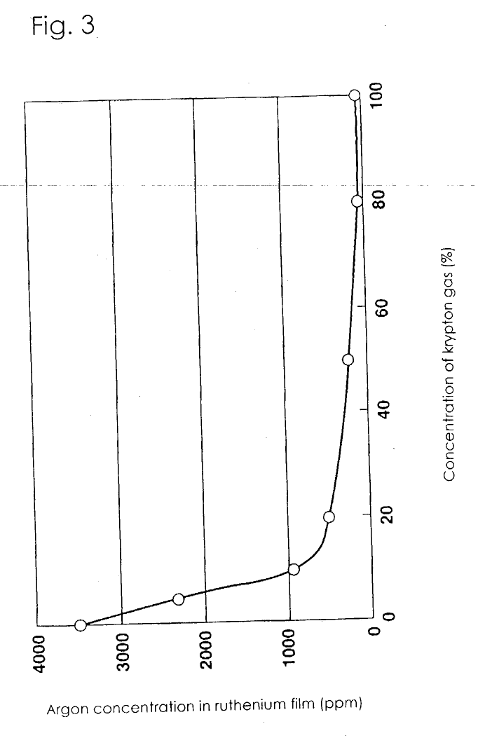

FIG. 3 illustrates the concentration of argon atoms contained in the ruthenium underlayer measured by Auger spectroscopy as a function of the concentration of krypton gas in the deposition process gas. The similar result was obtained when xenon gas was used in place of krypton gas. FIG. 3 shows that the argon gas concentration contained in the ruthenium underlayer decreases below 1,000 ppm when the krypton gas concentration in the deposition process gas is larger than 10%. On the other hand, FIG. 2 shows that krypton or xenon gas concentration in the deposition process gas is necessarily at least 10% in order to obtain satisfactory value of coercive force Hc. Therefore, FIG. 3 demonstrates that argon concentration need to be 1,000 ppm or below to attain excellent characteristic.

In a second example, a magnetic recording medium having structure of FIG. 1 was produced in the same manner as the first example, except that the thickness of the ruthenium underlayer was 30 nm and the deposition process gas was argon gas mixed with 90% krypton, while the pressure of the deposition atmosphere was varied.

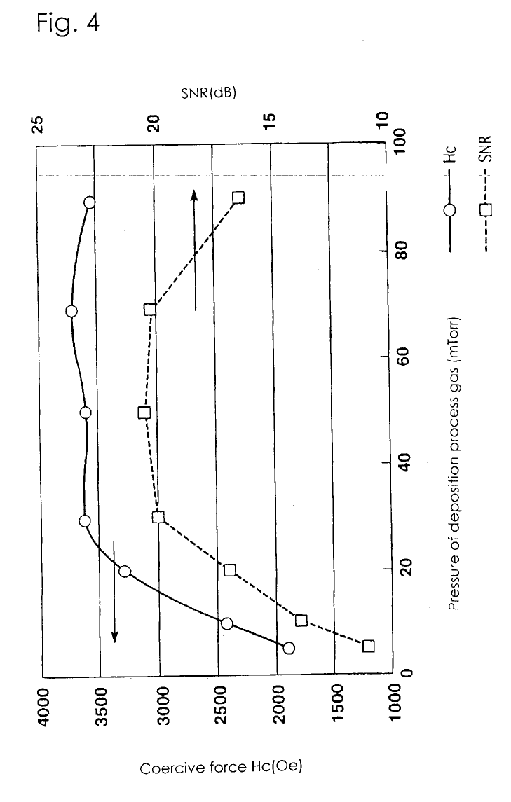

FIG. 4 shows the coercive force He and the signal to noise ratio at readout density of 300 kFCI as a function of the pressure of the deposition atmosphere. The measurement of the SNR was conducted on a spinning stand tester equipped with a GMR (giant magneto-resistance) head with a write track width of 1 μm, a gap length of 0.25 μm, a read track width of 0.7 μm, and a shield gap length of 0.12 μm. The head flying height was 20 nm. FIG. 4 shows that with increase of the pressure, the coercive force Hc and the SNR increase initially, reach their maximum, and then decrease. It has been demonstrated that to achieve excellent characteristics, the pressure of the deposition atmosphere should be in the range from 30 mTorr to 70 mTorr.

As described above, the process of sputtering the nonmagnetic underlayer in the present invention uses one type of inert gas, for example argon, mixed with another type of inert gas, for example krypton or xenon, which has the atomic weight and the atomic radius larger than those of argon. Such deposition process gas can favorably control fine structure of the nonmagnetic underlayer. The argon atoms entrapped in the film of the underlayer can be reduced below 1,000 ppm. As a result, a precise film of the underlayer can be formed, which is suitable to control the structure of the granular magnetic layer. Since the inert gas atoms that recoil from the target and collide with the substrate during the deposition process decrease, shock against the thin film during deposition is reduced, and control of the film structure can be further facilitated.

The present invention uses a deposition atmosphere gas containing argon and at least 10% of krypton or xenon. More preferably, a gas containing at least 50% of krypton or xenon is used. The maximum effect for structure control of the granular magnetic layer is obtained by the use of gas containing at least 80% of krypton or xenon.

The pressure of the deposition atmosphere is controlled in the range from 30 mTorr to 70 mTorr according to the invention. As a result, fine structure of the magnetic layer is controlled through control of fine structure of the nonmagnetic underlayer, to obtain a magnetic recording medium exhibiting excellent performances.

The deposition process in the medium according to the invention does not need substrate heating. As a result, simplification of the production process and reduction of production cost can be achieved. At the same time, plastics, which are inexpensive material, can be used for a substrate.

Given the disclosure of the present invention, one versed in the art would appreciate that there may be other embodiments and modifications within the scope and spirit of the present invention. Accordingly, all modifications and equivalents attainable by one versed in the art from the present disclosure within the scope and spirit of the present invention are to be included as further embodiments of the present invention. The scope of the present invention accordingly is to be defined as set forth in the appended claims.

The disclosure of the priority applications, JP PA 2001-359959, in its entirety, including the drawings, claims, and the specification thereof, is incorporated herein by reference.

What is claimed is:

1. A magnetic recording medium comprising:
a nonmagnetic substrate;
a nonmagnetic underlayer containing at least one metal selected from a group consisting of Ru, Os, and Re laminated on the substrate; and
a magnetic layer composed of ferromagnetic grains and nonmagnetic grain boundaries surrounding the ferromagnetic grains laminated on the underlayer,
wherein the underlayer contains less than 1,000 ppm of argon.

2. A magnetic recording medium according to claim 1, wherein the nonmagnetic underlayer is formed of a film structure composed of fine particles

3. A magnetic recording medium according to claim 2, wherein the film structure of the underlayer controls the structure of the magnetic layer.

4. A method of manufacturing a magnetic recording medium comprising the steps of:
depositing a nonmagnetic underlayer containing at least one metal selected from a group consisting of Ru, Os, and Re on a nonmagnetic substrate by reactive sputtering in a gas atmosphere containing at least one type of inert gas that reduces the atom count of the inert gas remaining in the underlayer; and
depositing a magnetic layer composed of ferromagnetic crystal grains and nonmagnetic grain boundaries surrounding said grains on the underlayer.

5. A method of manufacturing a magnetic recording medium according to claim 4, wherein the inert gas is krypton or xenon.

6. A method of manufacturing a magnetic recording medium according to claim 4, wherein the gas atmosphere contains at least two types of inert gases to reduce the atom count of at least one of the inert gases remaining in the underlayer to a predetermined level.

7. A method of manufacturing a magnetic recording medium according to claim 6, wherein the concentration of the atoms of one of the inert gases remaining in the underlayer is reduced by mixing the one inert gas with a different inert gas having larger atomic weight and radius.

8. A method of manufacturing a magnetic recording medium according to claim 4, wherein the concentration of the atoms of one of the inert gases remaining in the underlayer is reduced by mixing the one inert gas with different inert gas having larger atomic weight and radius.

9. A method of manufacturing a magnetic recording medium according to claim 8, the one inert gas is argon and the different inert gas is krypton or xenon for reducing argon remaining in the underlayer.

10. A method of manufacturing a magnetic recording medium according to claim 9, wherein the gas atmosphere contains sufficient amount of krypton or xenon to reduce argon remaining in the underlayer to less than 1,000 ppm.

11. A method of manufacturing a magnetic recording medium according to claim 7, the one inert gas is argon and the different inert gas is krypton or xenon for reducing argon remaining in the underlayer.

12. A method of manufacturing a magnetic recording medium according to claim 11, wherein the gas atmosphere contains sufficient amount of krypton or xenon to reduce argon remaining in the underlayer to less than 1,000 ppm.

13. A method of manufacturing a magnetic recording medium according to claim 12, wherein the gas atmosphere contains at least 10% of krypton or xenon.

14. A method of manufacturing a magnetic recording medium according to claim 12, wherein the gas atmosphere contains at least 50% of krypton or xenon.

15. A method of manufacturing a magnetic recording medium according to claim 12, wherein the gas atmosphere contains at least 80% of krypton or xenon.

16. A method of manufacturing a magnetic recording medium according to claim 12, wherein the gas atmosphere is pressurized to a range of 30-70 mTorr.

17. A method of manufacturing a magnetic recording medium according to claim 13, wherein the gas atmosphere is pressurized to a range of 30-70 mTorr.

18. A method of manufacturing a magnetic recording medium according to claim 14, wherein the gas atmosphere is pressurized to a range of 30-70 mTorr.

19. A method of manufacturing a magnetic recording medium according to claim 15, wherein the gas atmosphere is pressurized to a range of 30-70 mTorr.

20. A method of manufacturing a magnetic recording medium according to claim 4, wherein the nonmagnetic underlayer is a film structure composed of fine particles.

21. A method for manufacturing a magnetic recording medium according to claim 4, wherein the underlayer and the magnetic layer are deposited without preheating the nonmagnetic substrate.

22. A magnetic recording medium produced according to claim 4.
